(19) United States
(12) Patent Application Publication
(10) Pub. No.: US 2026/0082837 A1
(43) Pub. Date: Mar. 19, 2026

(54) METHOD FOR MANUFACTURING SEMICONDUCTOR DEVICE

(71) Applicant: Resonac Corporation, Minato-ku, Tokyo (JP)

(72) Inventors: Yoshiki MARUYAMA, Minato-ku, Tokyo (JP); Tadashi OKUDA, Minato-ku, Tokyo (JP); Shizu FUKUZUMI, Minato-ku, Tokyo (JP)

(21) Appl. No.: 18/857,188

(22) PCT Filed: Apr. 12, 2023
(86) PCT No.: PCT/JP2023/014899

§ 371 Date: Dec. 9, 2025

(51) Int. Cl. H01L 21/311; H01L 21/18; H01L 21/3105

(52) U.S. Cl. CPC H10P 50/287; H10P 10/128; H10P 95/06; H10P 95/08

(57) ABSTRACT

As an example, the present invention relates to a hybrid bonding method using an organic insulating layer as an insulating layer. In the hybrid bonding method using an organic insulating layer, there may be a difference in thermal expansion between a terminal electrode made of metal or the like and the organic insulating layer due to heating at the time of bonding, and it is necessary to provide a predetermined level difference D between a tip end surface of the terminal electrode and a surface of the organic insulating layer in advance. In the present invention, in order to provide the level difference D, the surface of the semiconductor substrate 100 is irradiated with plasma (e.g. argon plasma). In this plasma irradiation, an organic insulating layer 102 is etched with plasma such that a surface 102a of the organic insulating layer 102 of the semiconductor substrate 100 is on the farther side than a tip end surface 103a of an electrode 103.

### TECHNICAL FIELD

The present disclosure relates to a method for manufacturing a semiconductor device.

### BACKGROUND ART

Patent Literatures 1 to 3 disclose examples of a hybrid bonding technique used in a wafer-to-wafer (W2 W) bonding process or a chip-on-wafer (CoW) bonding process in three-dimensional mounting of a semiconductor device.

### CITATION LIST

### Patent Literature

Patent Literature 1: Japanese Unexamined Patent Publication No. 2021-197430
Patent Literature 2: Japanese Unexamined Patent Publication No. 2021-197431
Patent Literature 3: Japanese Unexamined Patent Publication No. 2018-528622

### SUMMARY OF INVENTION

### Technical Problem

In the hybrid bonding technique described in Patent Literature 1 and the like, an organic material (resin) may be used for an insulating portion. In this case, a difference in coefficient of thermal expansion (linear thermal expansion coefficient CTE) between the metal material constituting the terminal electrode and the organic material constituting the insulating portion may cause a shift in the position of the surface, leading to occurrence of bonding failure in the insulating portion or the terminal electrode. For this reason, a method of easily providing a desired level difference in advance between a surface of an organic insulating layer and a tip end surface of an electrode in a semiconductor substrate used for hybrid bonding is desired.

An object of the present disclosure is to provide a method for manufacturing a semiconductor device capable of easily providing a desired level difference between a surface of an organic insulating layer and a tip end surface of an electrode in a semiconductor substrate, in a hybrid bonding method using the organic insulating layer.

### Solution to Problem

[1] A method for manufacturing a semiconductor device according to one aspect of the present disclosure includes: preparing a first semiconductor substrate including a first substrate body, and a first organic insulating layer and a first electrode which are provided on a surface of the first substrate body; and irradiating a surface of the first semiconductor substrate with plasma. In the irradiating with plasma, at least the first organic insulating layer is etched with plasma such that a surface of the first organic insulating layer is closer to the first substrate body than a tip end surface of the first electrode.

In the method for manufacturing a semiconductor device, at least the first organic insulating layer is etched with plasma such that a surface of the first organic insulating layer is closer to the first substrate body than a tip end surface of the first electrode. In this case, although both the first organic insulating layer and the first electrode are irradiated with plasma, the amount of etching with plasma varies depending on the difference in elastic modulus between the first organic insulating layer and the first electrode. Therefore, according to this manufacturing method, the desired level difference can be easily provided between the surface of the organic insulating layer and the tip end surface of the electrodes of the semiconductor substrate, in the hybrid bonding method using the insulating layer, by changing the plasma conditions according to the materials of the organic insulating layer and the electrode, the difference in elastic modulus between the organic insulating layer and the electrode, or the like.

[2] In the method for manufacturing a semiconductor device according to the above-described [1], preferably, in the irradiating with plasma, the first semiconductor substrate is irradiated with argon plasma. In this case, the level difference between the surface of the organic insulating layer and the tip end surface of the electrode in the semiconductor substrate can be easily adjusted by a desired value.

[3] In the method for manufacturing a semiconductor device according to the above-described [1] or [2], preferably, in the irradiating with the plasma, a flow rate of the plasma gas is 3.38×10⁻² Pa·m³/sec (20 sccm) to 1.69 Pa·m³/sec (1,000 sccm). When the flow rate of the plasma gas is 3.38×10⁻² Pa·m³/sec (20 sccm) or more, etching with plasma is promoted, and a level difference between the surface of the organic insulating layer and the tip end surface of the electrode in the semiconductor substrate can be set to a desired value at an early stage. On the other hand, when the flow rate of the plasma gas is 1.69 Pa·m³/sec (1000 sccm) or less, it is possible to suppress the roughening of the surface of the organic insulating layer and the electrode due to the plasma.

[4] In the method for manufacturing a semiconductor device according to any one of the above-described [1] to [3], preferably, in the irradiating with the plasma, a plasma output is 10 W to 1,000 W. When the plasma output is 10 W or more, etching with plasma is promoted, and a level difference between the surface of the organic insulating layer and the tip end surface of the electrode in the semiconductor substrate can be set to a desired value at an early stage. On the other hand, when the plasma output is 1,000 W or less, it is possible to suppress the roughening of the surfaces of the organic insulating layer and the electrode due to the plasma.

[5] In the method for manufacturing a semiconductor device according to any one of the above-described [1] to [4], preferably, in the irradiating with plasma, a plasma treatment time is 30 seconds or more. When the plasma treatment time is 30 seconds or more, etching with plasma is promoted, and a level difference between the surface of the organic insulating layer and the tip end surface of the electrode in the semiconductor substrate can be set to a desired value at an early stage.

[6] In the method for manufacturing a semiconductor device according to any one of the above-described [1] to [5], preferably, the first organic insulating layer has an elastic modulus of 7.5 GPa or less. In this case, a desired level difference between the surface of the organic insulating layer and the tip end surface of the electrode in the semiconductor substrate can be easily provided.

[7] In the method for manufacturing a semiconductor device according to any one of the above-described [1] to [6], in the irradiating with plasma, the surface of the first semiconductor substrate may be irradiated with plasma such that a level difference distance between the surface of the first organic insulating layer and the tip end surface of the first electrode is 40 nm to 100 nm. In this case, when the first semiconductor substrate is bonded to another substrate by hybrid bonding, the shift amount between the surface of the first organic insulating layer and the tip end surface of the first electrode decreases due to thermal expansion, and the first semiconductor substrate and the other substrate can be bonded to each other more reliably.

[8] In the method for manufacturing a semiconductor device according to any one of the above-described [1] to [6], in the irradiating with plasma, the surface of the first semiconductor substrate may be irradiated with plasma such that a level difference distance between the surface of the first organic insulating layer and the tip end surface of the first electrode is 60 nm to 80 nm. In this case, when the first semiconductor substrate is bonded to another substrate by hybrid bonding, the shift amount between the surface of the first organic insulating layer and the tip end surface of the first electrode decreases due to thermal expansion, and the first semiconductor substrate and the other substrate can be bonded to each other more reliably.

[9] The method for manufacturing a semiconductor device according to any one of the above-described [1] to [8], preferably, further includes polishing the first organic insulating layer and the first electrode which are provided on the surface of the first semiconductor substrate, and the polishing the first semiconductor substrate is performed before the irradiating with the plasma. The level difference can be adjusted to a desired value while reducing the surface roughness of the surface of the first organic insulating layer and the tip end surface of the first electrode in the first semiconductor substrate in the polishing, but it is difficult to adjust the fine level difference. Therefore, when the desired level difference amount cannot be obtained in the polishing, the level difference amount can be further adjusted by performing the irradiating with plasma after the polishing. Therefore, according to this manufacturing method, it is possible to reduce bonding failure in hybrid bonding.

[10] In the method for manufacturing a semiconductor device according to the above-described [9], preferably, in the polishing the first semiconductor substrate, polishing is performed such that a surface roughness Ra of each of the surfaces of the first organic insulating layer and the first electrode is 5 nm or less, preferably 1 nm or less. In this case, it is possible to more reliably reduce bonding failure in hybrid bonding.

[11] The method for manufacturing a semiconductor device according to any one of the above-described [1] to [10], may further include preparing a second semiconductor substrate including a second substrate body, and a second organic insulating layer and a second electrode which are provided on a surface of the second substrate body; aligning the second electrode of the second semiconductor substrate with the first electrode of the first semiconductor substrate; and heating and pressurizing the first semiconductor substrate and the second semiconductor substrate to bond the first organic insulating layer and the second organic insulating layer to each other and bond the first electrode and the second electrode to each other. In this case, the first semiconductor substrate and the second semiconductor substrate can be bonded by hybrid bonding. The hybrid bonding referred to herein may be hybrid bonding used in any of a wafer-to-wafer (W2 W) bonding process and a chip-on-wafer (CoW) bonding process.

[12] The method for manufacturing a semiconductor device according to the above-described [11], may further include irradiating a surface of the second semiconductor substrate with plasma, and in the irradiating the second semiconductor substrate with plasma, at least the second organic insulating layer may be etched with plasma such that a surface of the second organic insulating layer is closer to the second substrate body than a tip end surface of the second electrode. In this case, the desired level difference can be easily provided between the surface of the organic insulating layer and the tip end surface of the electrodes in the semiconductor substrate even in the second semiconductor substrate by changing the plasma conditions according to the materials of the organic insulating layer and the electrode, the difference in elastic modulus between the organic insulating layer and the electrode, or the like.

[13] In the method for manufacturing a semiconductor device according to any one of the above-described [1] to [12], the resin material contained in the first organic insulating layer may contain bismaleimide, polyimide, a polyimide precursor, polyamideimide, benzocyclobutene (BCB), polybenzoxazole (PBO), or a PBO precursor. Since these materials are liquid or soluble in a solvent, the first organic insulating layer can be easily produced by, for example, spin coating or the like, and a thin film can be easily formed. In addition, since these materials have high heat resistance, the materials can withstand high temperatures when the first semiconductor substrate is bonded to the second semiconductor substrate, and the substrates can be bonded to each other more reliably. Note that the second organic insulating layer of the second semiconductor substrate may be formed to contain the above-described organic material. In this case as well, the same effects can be obtained.

### Advantageous Effects of Invention

According to the present disclosure, it is possible to easily provide a desired level difference between a surface of an organic insulating layer and a tip end surface of an electrode in a semiconductor substrate, in a hybrid bonding method using the organic insulating layer.

### BRIEF DESCRIPTION OF DRAWINGS

FIG. 1 is a cross-sectional view schematically showing an example of a semiconductor device (CoW) manufactured by a method for manufacturing a semiconductor device according to an embodiment of the present disclosure.

FIG. 2 is a view sequentially showing a method for manufacturing the semiconductor device shown in FIG. 1.

FIG. 3 is a view schematically showing a plasma process in the method for manufacturing the semiconductor device shown in FIG. 2.

FIG. 4 is a view showing a bonding method in the method for manufacturing the semiconductor device, shown in FIG. 2.

### DESCRIPTION OF EMBODIMENTS

Hereinafter, some embodiments of the present disclosure will be described in detail with reference to the drawings as necessary. In the following description, the same or corresponding parts will be given the same reference numerals, and redundant description thereof will be omitted. Unless otherwise specified, the positional relationship such as up, down, left, and right is based on the positional relationship shown in the drawings. The use of the terms “left”, “right”, “front”, “back”, “up”, “down”, “above”, “below”, and the like in the description and claims of the present specification is intended for description and is not necessarily meant to be a permanent relative position thereof. The dimensional ratios in the drawings are not limited to the shown ratios.

In the present specification, the term “layer” includes a structure having a shape partially formed in addition to a structure having a shape formed on the entire surface when observed as a plan view. In the present specification, the term “step” includes not only an independent step but also cases where the step cannot be clearly distinguished from other steps as long as an intended action of the step is achieved. A numerical range indicated using “to” indicates a range including numerical values described before and after “to” as a minimum value and a maximum value, respectively.

### (Configuration of Semiconductor Device)

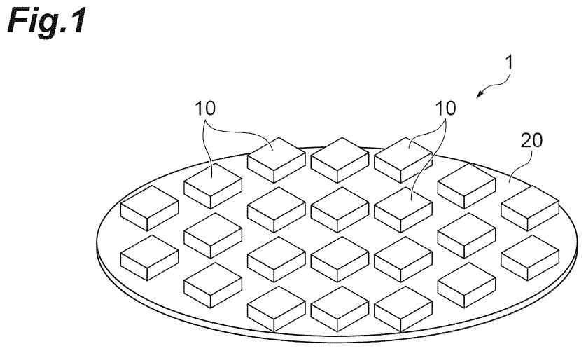

FIG. 1 is a cross-sectional view schematically showing an example of a semiconductor device manufactured by a manufacturing method according to the present embodiment. As shown in FIG. 1, a semiconductor device 1 is, an example of a semiconductor package, includes a plurality of semiconductor chips 10 and a semiconductor substrate 20, and has a chip-on-wafer (CoW) structure. The plurality of semiconductor chips 10 is produced by singulating a semiconductor substrate 100, which will be described later, by dicing. The plurality of semiconductor chips 10 are mounted on the semiconductor substrate 20 to form a three-dimensional mounting structure. The semiconductor substrate 20 may be a substrate in which a plurality of semiconductor chips such as a large scale integrated circuit (LSI) chip or a complementary metal oxide semiconductor (CMOS) sensor is formed at places corresponding to the respective semiconductor chips 10. Each semiconductor chip 10 may be, for example, a semiconductor chip such as an LSI or a memory. The plurality of semiconductor chips 10 and the semiconductor substrate 20 are finely bonded to each other by hybrid bonding described later such that each terminal electrode and the insulating layers around the terminal electrodes are firm attached and positioned without shift in the position. The semiconductor device 1 may be further singulated into individual semiconductor devices including one semiconductor chip 10 further singulated from the configuration shown in FIG. 1 and a substrate part which is a part of the semiconductor substrate 20 corresponding to one semiconductor chip 10. The manufacturing method according to the present embodiment may be applied to a W2 W bonding process, and in this case, the semiconductor substrates are bonded to each other.

### (Method for Manufacturing Semiconductor Device)

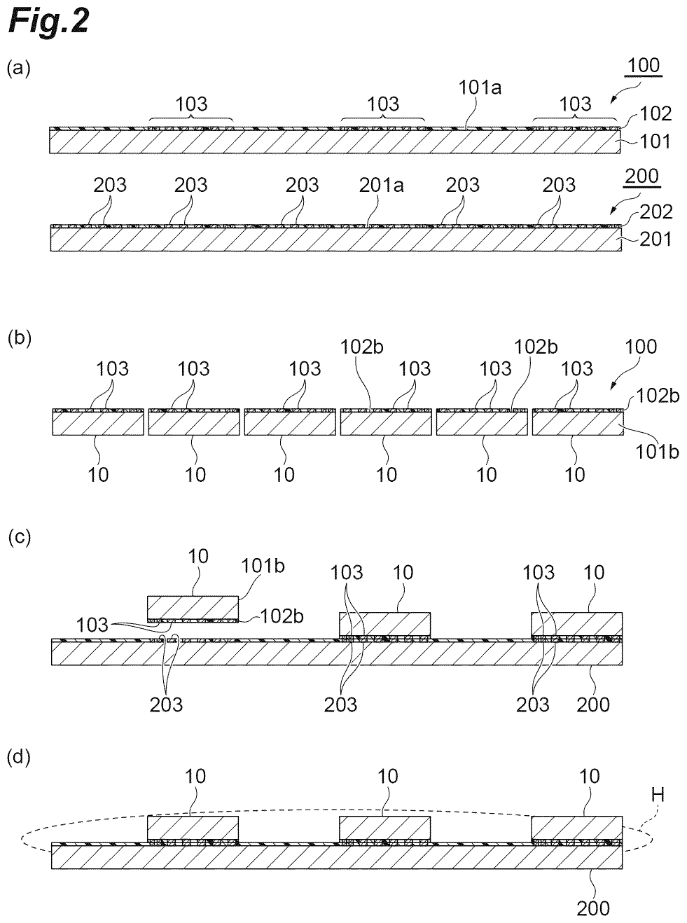

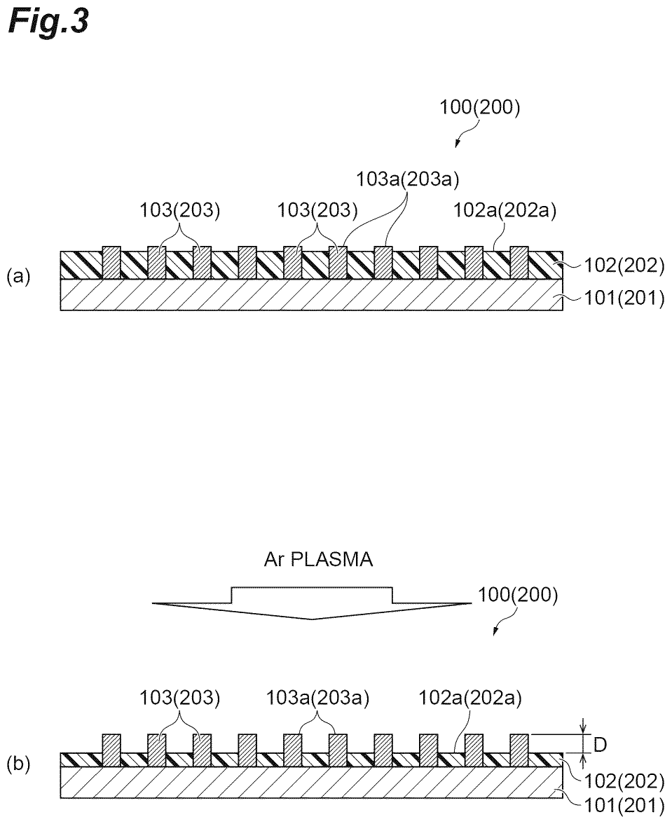

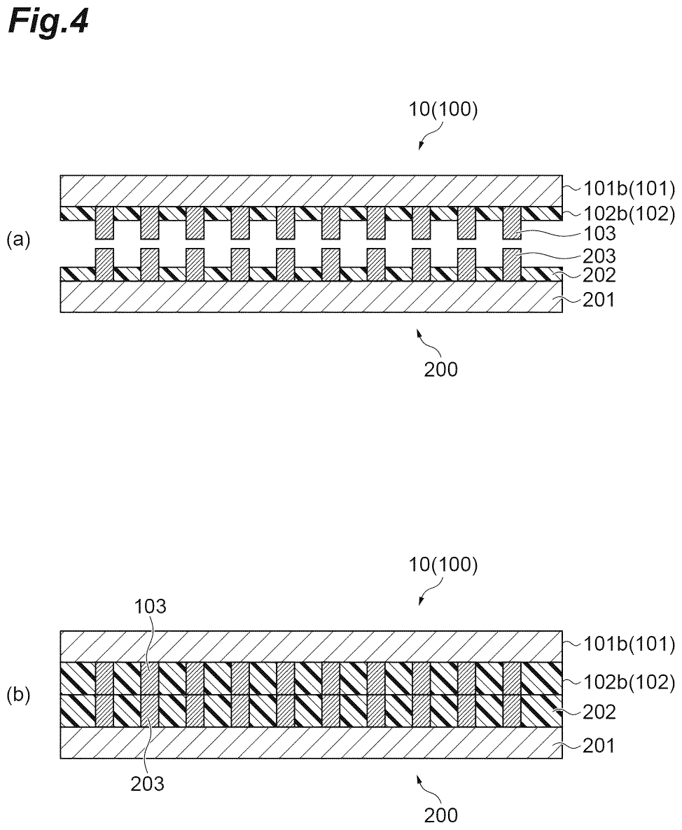

Next, the method for manufacturing the semiconductor device 1 will be described with reference to FIG. 2 to FIG. 4. FIG. 2 is a view sequentially showing a method for manufacturing the semiconductor device shown in FIG. 1. FIG. 3 is a view schematically showing a plasma process in the method for manufacturing the semiconductor device, shown in FIG. 2. FIG. 4 is a view showing a bonding method in the method for manufacturing the semiconductor device, shown in FIG. 2.

The semiconductor device 1 can be manufactured, for example, through the following steps (a) to (j).

(a) a step of preparing a semiconductor substrate 100 corresponding to a plurality of semiconductor chips 10, that is, the semiconductor substrate 100 including a substrate body 101, an insulating layer 102, and a plurality of electrodes 103.

(b) a step of preparing a semiconductor substrate 200 including a substrate body 201, an insulating layer 202, and a plurality of electrodes 203.

(c) a step of polishing the insulating layer 102 of the semiconductor substrate 100 together with the electrodes 103.

(d) a step of polishing the insulating layer 202 of the semiconductor substrate 200 together with the electrodes 203.

(e) a step of irradiating the insulating layer 102 and the electrodes 103 of the semiconductor substrate 100 with plasma.

(f) a step of irradiating the insulating layer 202 and the electrodes 203 of the semiconductor substrate 200 with plasma.

(g) a step of singulating the semiconductor substrate 100 and acquiring a plurality of semiconductor chips 10 each including an insulating layer part 102b corresponding to the insulating layer 102 and the electrode 103.

(h) a step of aligning the electrodes 103 of each of the plurality of semiconductor chips 10 with the electrodes 203 of the semiconductor substrate 200.

(i) a step of bonding each of the insulating layer parts 102b of the plurality of semiconductor chips 10 and the insulating layer 202 of the semiconductor substrate 200 to each other.

(j) a step of bonding the electrode 103 of each of the plurality of semiconductor chips 10 and the electrodes 203 of the semiconductor substrate 200 to each other.

[Step (a) and Step (b)]

The step (a) is a step of preparing the semiconductor substrate 100 (second semiconductor substrate) which corresponds to the plurality of semiconductor chips 10 and is a silicon substrate in which an integrated circuit including semiconductor elements, wiring connecting the semiconductor elements, and the like is formed. In the step (a), as shown in FIG. 2 (a), the plurality of electrodes 103 (second electrodes) made of copper, aluminum, or the like are provided at predetermined intervals on a surface 101a of a substrate body 101 (second substrate body) made of silicon or the like, and the insulating layer 102 (second organic insulating layer) made of an inorganic material or an organic material is provided. The electrode 103 is a terminal electrode for exposing the integrated circuit or the like formed in the semiconductor substrate 100 to the outside through the insulating layer 102. The plurality of electrodes 103 may be provided after the insulating layer 102 is provided on the surface 101a of the substrate body 101, or the insulating layer 102 may be provided after the plurality of electrodes 103 is provided on the surface 101a of the substrate body 101.

The step (b) is a step of preparing the semiconductor substrate 200 (first semiconductor substrate) which is a silicon substrate in which an integrated circuit including semiconductor elements, wiring connecting the semiconductor elements, and the like is formed. In the step (b), as shown in FIG. 2 (a), the plurality of electrodes 203 (first electrodes) made of copper, aluminum, or the like are provided at predetermined intervals on a surface 201a of a substrate body 201 (first substrate body) made of silicon or the like, and the insulating layer 202 (first organic insulating layer) made of an inorganic material or an organic material is provided. The electrode 203 is a terminal electrode for exposing the integrated circuit or the like formed in the semiconductor substrate 200 to the outside through the insulating layer 202. The plurality of electrodes 203 may be provided after the insulating layer 202 is provided on the surface 201a of the substrate body 201, or the insulating layer 202 may be provided after the plurality of electrodes 203 are provided on the surface 201a of the substrate body 201.

The insulating layer 102 and the insulating layer 202 used in the step (a) and the step (b) contain an organic material. The organic material used for the insulating layer is, for example, polyimide, a polyimide precursor (for example, a polyimide amic ester or a polyamic acid), polyamideimide, benzocyclobutene (BCB), polybenzoxazole (PBO), or a PBO precursor. These organic materials have, for example, a lower elastic modulus than inorganic materials such as silicon oxide (SiO₂), and are soft materials. By using such an organic material, when the insulating layers are bonded to each other in the step (i) to be described later, even when fine foreign matter (debris) exists on the insulating layer, the foreign matter is absorbed into the insulating layer to prevent bonding failure due to the foreign matter, and the insulating layers can be reliably bonded to each other. The elastic moduli of the organic material constituting the insulating layer 102 and the insulating layer 202 may be, for example, 7.0 GPa or less, 5.0 GPa or less, 3.5 GPa or less, 3.0 GPa or less, or 2.5 GPa or less. The elastic modulus here means Young's modulus. Since the insulating layer is made of an organic material having such an elastic modulus, the thickness of the insulating layer can be easily reduced by plasma irradiation in the steps (e) and (f) to be described later. The coefficient of thermal expansion of the organic material constituting the insulating layer 102 and the insulating layer 202 is preferably 70 ppm/K or less, and may be more preferably 50 ppm/K or less.

Since the organic material used for the insulating layer is liquid or soluble in a solvent, each insulating layer can be easily formed as a thin layer by spin coating or the like. Furthermore, since these organic materials have heat resistance, the organic materials can withstand the temperature (for example, a high temperature of 300° C. or higher) at the time of bonding the electrode 103 and the electrode 203 to each other in the step (j) to be described later, and the bonding between the insulating layers is not deteriorated due to the high temperature. As the organic material constituting the insulating layer 102 and the insulating layer 202, a photosensitive resin, a thermosetting non conductive film (NCF), or a thermosetting resin may be used. The organic material may be an underfill material. Note that the insulating layer 102 and the insulating layer 202 may be insulating layers containing both an inorganic material and an organic material, or one insulating layer may be formed of an inorganic material and the other insulating layer may be formed of an organic material. The inorganic material used for the insulating layer is, for example, silicon oxide (SiO₂) or the like.

The thickness of the insulating layer 102 may be 20 μm or less. By sufficiently reducing the thickness of the insulating layer 102, the wiring and the like formed from the electrode 103 can have a finer configuration. For example, the minimum size (electrode width) of the electrode 103 formed in the insulating layer 102 is defined by the thickness of the insulating layer 102 and the aspect ratio of the photosensitive material to be used. When the aspect ratio of the photosensitive material is, for example, 1:1 (opening width:depth), the thickness of the insulating layer 102 is 20 μm or less, and accordingly, the electrode width of the electrode 103 can be 20 μm or less. The thickness of the insulating layer 102 may be larger than 20 μm. In this case, when the insulating layers are bonded to each other in the step (i) to be described later, more foreign matter can be embedded in the resin insulating layer 102, and the insulating layers can be more reliably bonded to each other. It is also possible to improve the adhesiveness between the insulating layers by alleviating the stress at the time of bonding the insulating layers with any of the resin insulating layers.

Furthermore, the thickness of the insulating layer 102 may be 4 μm or more. In this case, by embedding the minute foreign matter in the resin insulating layer, it is possible to improve the connection between the insulating layer 102 and the insulating layer 202 even when the minute foreign matter remains. For example, the size of the foreign matter that can be embedded in the insulating layer 102 is defined by the thickness of the resin insulating layer 102. When the thickness of the insulating layer 102 is, for example, 4 μm, foreign matter having a diameter or width of 4 μm can be embedded in the insulating layer 102. That is, according to this manufacturing method, even when there is debris smaller than the thickness of the insulating layer 102, it is possible to improve the connection between the insulating layer 102 and the insulating layer 202 by embedding the debris in the resin insulating layer. Similarly to the insulating layer 102, the thickness of the insulating layer 202 may be 20 μm or less, may be larger than 20 μm, or may be 4 μm or more. As described above, the insulating layer 202 may embed debris.

[Step (c) and Step (d)]

The step (c) is a step of polishing the semiconductor substrate 100. In the step (c), the surface of the insulating layer 102 provided with the electrodes 103 is polished using a chemical mechanical polishing (CMP) method. This polishing is preferably performed before the step (e) of irradiating with plasma. This is because the surface of the insulating layer 102 may be roughened by the plasma irradiation in the step (e), and the average roughness of the surface of the insulating layer 102 is reduced in advance before bonding by hybrid bonding. By such polishing, the average roughness of the surface of the insulating layer 102 is set to 5 nm or less, preferably 1 nm or less, and hybrid bonding to be described later becomes possible. By this polishing, debris on the surface of the semiconductor substrate 100 may be removed. In this polishing step, a part of the level difference between a surface 102a of the insulating layer 102 and a tip end surface 103a of the electrode 103 may be formed.

The step (d) is a step of polishing the semiconductor substrate 200. In the step (d), the surface of the insulating layer 202 provided with the electrodes 203 is polished using a CMP method. This polishing is preferably performed before the step (f). This is because the surface of the insulating layer 202 may be roughened by the plasma irradiation in the step (f) similarly to the step (c), and the average roughness of the surface of the insulating layer 202 is reduced before bonding by hybrid bonding. By such polishing, the average roughness of the surface of the insulating layer 202 is set to 5 nm or less, preferably 1 nm or less, and hybrid bonding to be described later becomes possible. By this polishing, debris on the surface of the semiconductor substrate 200 may be removed. In this polishing step, a part of the level difference between the surface 202a of the insulating layer 202 and the tip end surface 203a of the electrode 203 may be formed.

In the step (c) and the step (d), polishing may be performed such that the thickness of the insulating layer 102 is equal to the thickness of the insulating layer 202, but for example, polishing may be performed such that the thickness of the insulating layer 102 is larger than the thickness of the insulating layer 202. On the other hand, polishing may be performed such that the thickness of the insulating layer 102 is smaller than the thickness of the insulating layer 202. In a case where the thickness of the insulating layer 102 is larger than the thickness of the insulating layer 202, and the insulating layer 102 is formed of an organic material, it is possible to contain most of debris adhering to the bonding interface at the time of singulating the semiconductor chips 10 or at the time of chip mounting, and it is possible to reduce bonding failure. On the other hand, when the thickness of the insulating layer 102 is smaller than the thickness of the insulating layer 202, it is possible to reduce the height of the semiconductor chip 10 to be mounted, that is, the semiconductor device 1.

[Step (e) and Step (f)]

The step (e) is a step of irradiating the insulating layer 102 and the electrodes 103 of the semiconductor substrate 100 with plasma. In the step (e), as shown in FIGS. 3 (a) and (b), the insulating layer 102 is etched with plasma such that the surface 102a of the insulating layer 102 is closer to the substrate body 101 (lower side) than the tip end surface 103a of the electrode 103. The plasma used in the step (e) is, for example, argon (Ar) plasma, and etching is performed by disposing the semiconductor substrate 100 in a decompression chamber and irradiating the surface of the semiconductor substrate 100 with argon plasma. As conditions of the argon plasma, the flow rate of the plasma gas (argon gas) may be 3.38× 10⁻² Pa·m³/sec (20 sccm) to 1.69 Pa·m³/sec (1,000 sccm) (each means a flow rate at 1 atm and 0° C.), the plasma output may be 10 W to 1,000 W, and the plasma treatment time may be 30 seconds or more. The plasma treatment time may be 500 seconds or less. By such plasma irradiation, as shown in FIG. 3 (b), the level difference D between the surface 102a of the insulating layer 102 and the tip end surface 103a of the electrode 103 becomes 40 nm to 100 nm. The level difference D appears due to a difference in elastic modulus between the insulating layer 102 and the electrode 103. Plasma may be applied such that the level difference D between the surface 102a of the insulating layer 102 and the tip end surface 103a of the electrode 103 is 60 nm to 80 nm. The plasma to be used is preferably argon plasma from the viewpoint of an oxide film, but is not limited thereto, and oxygen plasma or the like may be used.

The step (f) is a step of irradiating the insulating layer 202 and the electrodes 203 of the semiconductor substrate 200 with plasma. In the step (f), similarly to the step (e), the insulating layer 202 is etched with plasma such that the surface 202a of the insulating layer 202 is closer to the substrate body 201 (lower side) than the tip end surface 203a of the electrode 203. The plasma used in the step (f) is, for example, argon (Ar) plasma, and etching is performed by disposing the semiconductor substrate 200 in a decompression chamber and irradiating the surface of the semiconductor substrate 200 with argon plasma. As conditions of the argon plasma, the flow rate of the plasma gas (argon gas) may be 3.38× 10⁻² Pa·m³/sec (20 sccm) to 1.69 Pa·m³/sec (1,000 sccm) (each means a flow rate at 1 atm and 0° C.), the plasma output may be 10 W to 1,000 W, and the plasma treatment time may be 30 seconds or more. The plasma treatment time may be 500 seconds or less. By such plasma irradiation, as shown in FIG. 3 (b), the level difference D between the surface 202b of the insulating layer 202 and the tip end surface 203a of the electrode 203 becomes 40 nm to 100 nm. The level difference D appears due to a difference in elastic modulus between the insulating layer 202 and the electrode 203. Plasma may be applied such that the level difference D between the surface 202b of the insulating layer 202 and the tip end surface 203a of the electrode 203 is 60 nm to 80 nm. The step is the same as the step (e) in that plasma other than argon may be used.

[Step (g)]

The step (g) is a step of singulating the semiconductor substrate 100 to acquire the plurality of semiconductor chips 10. When the polishing of the semiconductor substrate 200 is completed, the polished semiconductor substrate 100 is singulated in the step (g), and the plurality of semiconductor chips 10 (semiconductor substrate) each including the insulating layer part 102b corresponding to the insulating layer 102 and at least one electrode 103, are acquired. In the step (g), the semiconductor substrate 100 is disposed on a dicing tape, and is singulated into the plurality of semiconductor chips 10 by cutting means such as dicing from the insulating layer 102 toward the substrate body 101. When the semiconductor substrate 100 is diced, the insulating layer 102 may be coated with a protective material or the like, and then divided into individual pieces. By the step (g), the insulating layer 102 of the semiconductor substrate 100 is divided into insulating layer parts 102b corresponding to the respective semiconductor chips 10 as shown in FIG. 2 (b). The substrate body 101 is similarly divided into corresponding substrate parts 101b. As a dicing method of singulating the semiconductor substrate 100, for example, plasma dicing, stealth dicing, or laser dicing can be used. After the singulating by dicing is completed in the step (g), the singulated semiconductor chip 10 may be cleaned.

[Step (h)]

As shown in FIG. 2 (c) (left part) and FIG. 4 (a), the step (h) is a step of aligning the electrodes 103 of each of the plurality of semiconductor chips 10 with the electrodes 203 of the semiconductor substrate 200. In the step (h), the respective semiconductor chips 10 are aligned such that the respective electrodes 103 of the respective semiconductor chips 10 face the corresponding electrodes 203 of the semiconductor substrate 200. FIG. 4 (a) is an enlarged schematic view of a part of FIG. 2 (c). As shown in FIG. 4 (a), regarding the level before heating for bonding, a state where the level difference is formed between the insulating layer part 102b and the electrode 103 and between the insulating layer 202 and the electrode 203 is achieved. That is, the electrodes 103 and 203 protrude from the insulating layer part 102b and the surface of the insulating layer 202, respectively.

[Step (i)]

The step (i) is a step of bonding each of the insulating layer parts 102b of the plurality of semiconductor chips 10 and the insulating layer 202 of the semiconductor substrate 200 to each other. In the step (i), after removing the organic substance or the metal oxide adhering to the surfaces of each of the semiconductor chips 10 and the semiconductor substrate 200, the semiconductor chips 10 are aligned with the semiconductor substrate 200. When this alignment is completed, as shown in FIG. 2 (c) (right part) and FIG. 4 (b), the insulating layer part 102b of each of the plurality of semiconductor chips 10 is bonded to the insulating layer 202 of the semiconductor substrate 200 as hybrid bonding. At this time, the insulating layer parts 102b of the plurality of semiconductor chips 10 and the insulating layer 202 of the semiconductor substrate 200 may be uniformly heated and then bonded. By the heating for bonding, the insulating layer made of the organic material expands more than the electrodes, and the level difference between the insulating layer part 102b and the electrodes 103 and the level difference between the insulating layer 202 and the electrodes 203 are eliminated. Note that these level differences may be completely eliminated, the surfaces of the insulating layer part 102b and the electrodes 103 may be flush with each other, and the surfaces of the insulating layer 202 and the electrodes 203 may be flush with each other, or a level difference may remain slightly. The temperature difference between the semiconductor chips 10 and the semiconductor substrate 200 at the time of bonding is preferably, for example, 10° C. or less. By thermal bonding at such a uniform temperature, the insulating layer parts 102b and the insulating layer 202 are bonded to form insulating bonding parts, and the plurality of semiconductor chips 10 are mechanically firmly attached to the semiconductor substrate 200. Since the thermal bonding is performed at a uniform temperature, shift in the position or the like at the bonding place hardly occurs, and highly accurate bonding can be performed. At this attachment stage, the electrodes 103 of the semiconductor chips 10 and the electrodes 203 of the semiconductor substrate 200 are separated from each other and are not connected (but aligned). Note that the bonding of the semiconductor chips 10 to the semiconductor substrate 200 may be performed by another bonding method, for example, bonding by room-temperature bonding or the like.

[Step (j)]

The step (j) is a step of bonding the electrodes 103 of each of the plurality of semiconductor chips 10 and the electrodes 203 of the semiconductor substrate 200 to each other. When the bonding in the step (i) is completed, as shown in FIG. 2 (d), predetermined heat H or pressure or both is applied to bond the electrodes 103 of the plurality of semiconductor chips 10 and the electrodes 203 of the semiconductor substrate 200 as hybrid bonding in the step (j). When the electrodes 103 and the electrodes 203 are made of copper, the annealing temperature in the step (j) is preferably 150° C. to 400° C., and more preferably 200° C. to 300° C. By such bonding processing, an electrode joined part where the electrode 103 and the electrode 203 corresponding thereto are joined to each other is obtained, and each electrode 103 and each electrode 203 are mechanically and electrically firmly joined to each other. The electrode bonding in the step (j) is performed after the bonding in the step (i), but may be performed simultaneously with the bonding in the step (i). Thereafter, all the semiconductor chips 10 are bonded to the semiconductor substrate 200 to acquire the semiconductor device 1 shown in FIG. 1.

As described above, it is possible to acquire the semiconductor device 1 in which the plurality of semiconductor chips 10 are electrically and mechanically mounted at predetermined positions on the semiconductor substrate 200 with high accuracy. Thereafter, the semiconductor device (CoW) having the configuration shown in FIG. 1 may be further singulated to form each semiconductor device including one semiconductor chip 10 and a part of the semiconductor substrate 200 corresponding to the one semiconductor chip 10.

As described above, according to the method for manufacturing a semiconductor device according to the present embodiment, in the steps (e) and (f), the insulating layers 102 and 202 are etched with plasma such that the surfaces of the insulating layers 102 and 202 are closer to the substrate bodies 101 and 201 than the tip end surfaces of the electrodes 103 and 203. In this case, although both the insulating layers 102 and 202 and the electrodes 103 and 203 are irradiated with plasma, the amount of etching with plasma varies depending on the difference in elastic modulus between the two. Therefore, according to this manufacturing method, the desired level difference D can be easily provided between the surface of the insulating layer 202 and the tip end surfaces of the electrodes 103 and 203 of the semiconductor substrates 100 and 200, in the hybrid bonding method using the insulating layers 102 and 202, by changing the plasma conditions according to the materials of the organic insulating layer and the electrode, the difference in elastic modulus between the organic insulating layer and the electrode, or the like.

In the method for manufacturing a semiconductor device according to the present embodiment, it is preferable to irradiate the semiconductor substrates 100 and 200 with argon plasma in the steps (e) and (f). In this case, the level difference between the surfaces of the insulating layers 102 and 202 and the tip end surfaces of the electrodes 103 and 203 of the semiconductor substrates 100 and 200 can be easily adjusted by a desired value.

In the method for manufacturing a semiconductor device according to the present embodiment, in the steps (e) and (f), the flow rate of the plasma gas is preferably 3.38×10⁻² Pa·m³/sec (20 sccm) to 1.69 Pa·m³/sec (1,000 sccm). When the flow rate of the plasma gas is 3.38× 10⁻² Pa·m³/sec (20 sccm) or more, etching with plasma is promoted, and a level difference between the surfaces of the insulating layers 102 and 202 and the tip end surfaces of the electrodes 103 and 203 of the semiconductor substrates 100 and 200 can be set to a desired value at an early stage. On the other hand, when the flow rate of the plasma gas is 1.69 Pa·m³/sec (1,000 sccm) or less, it is possible to suppress the roughening of the surfaces of the insulating layers 102 and 202 and the electrodes 103 and 203 due to the plasma.

In the method for manufacturing a semiconductor device according to the present embodiment, the plasma output is preferably 10 W to 1,000 W in the steps (e) and (f). When the plasma output is 10 W or more, etching with plasma is promoted, and a level difference between the surfaces of the insulating layers 102 and 202 and the tip end surfaces of the electrodes 103 and 203 of the semiconductor substrates 100 and 200 can be set to a desired value at an early stage. On the other hand, when the plasma output is 1,000 W or less, it is possible to suppress the roughening of the surfaces of the insulating layers 102 and 202 and the electrodes 103 and 203 due to the plasma.

In the method for manufacturing a semiconductor device according to the present embodiment, the plasma treatment time is preferably 30 seconds or more in the steps (e) and (f). When the plasma treatment time is 30 seconds or more, etching with plasma is promoted, and a level difference between the surfaces of the insulating layers 102 and 202 and the tip end surfaces of the electrodes 103 and 203 of the semiconductor substrates 100 and 200 can be set to a desired value at an early stage.

In the method for manufacturing a semiconductor device according to the present embodiment, the elastic modulus of the insulating layers 102 and 202 are preferably 7.5 GPa or less. In this case, a desired level difference can be easily provided between the surfaces of the insulating layers 102 and 202 and the tip end surfaces of the electrodes 103 and 203 of the semiconductor substrates 100 and 200.

In the method for manufacturing a semiconductor device according to the present embodiment, in the steps (e) and (f), the surfaces of the semiconductor substrates 100 and 200 may be irradiated with plasma such that the level difference distance between the surfaces of the insulating layers 102 and 202 and the tip end surfaces of the electrodes 103 and 203 is 40 nm to 100 nm. In this case, when the semiconductor substrates 100 and 200 are bonded to each other, the shift amount between the surfaces of the insulating layers 102 and 202 and the tip end surfaces of the electrodes 103 and 203 is reduced by thermal expansion, and the semiconductor substrates 100 and 200 can be bonded to each other more reliably.

In the method for manufacturing a semiconductor device according to the present embodiment, in the steps (e) and (f), the surfaces of the semiconductor substrates 100 and 200 may be irradiated with plasma such that the level difference distance between the surfaces of the insulating layers 102 and 202 and the tip end surfaces of the electrodes 103 and 203 is 60 nm to 80 nm. In this case, when the semiconductor substrates 100 and 200 are bonded to each other by the hybrid bonding, the shift amount between the surfaces of the insulating layers 102 and 202 and the tip end surfaces of the electrodes 103 and 203 is reduced by thermal expansion, and the semiconductor substrates 100 and 200 can be bonded to each other more reliably.

The method for manufacturing a semiconductor device according to the present embodiment may include a step of polishing the insulating layers 102 and 202 and the electrodes 103 and 203 provided on a surface of the semiconductor substrates 100 and 200. The step of polishing the semiconductor substrates 100 and 200 may be preferably performed before the steps (e) and (f) of irradiating with plasma. Although the level difference between the surfaces of the insulating layers 102 and 202 and the tip end surfaces of the electrodes 103 and 203 of the semiconductor substrates 100 and 200 can be set to a desired value by irradiating with plasma, the surface roughness of the surfaces of the insulating layers 102 and 202 or the tip end surfaces of the electrodes 103 and 203 may be deteriorated depending on the plasma output situation. In the hybrid bonding, when the surface roughness of the bonding surface is deteriorated, there is a concern that the bonding in the hybrid bonding becomes defective. Therefore, in this manufacturing method, the surface roughness of the surface and the tip end surface roughened by plasma irradiation is reduced in advance by polishing. Therefore, according to this manufacturing method, it is possible to reduce bonding failure in hybrid bonding. In addition, in the polishing steps (c) and (d), it is also possible to set the level difference between the surface of the organic insulating layer and the tip end surface of the electrode to a desired value while reducing the surface roughness of the surface of the organic insulating layer and the tip end surface of the electrode of the semiconductor substrates 100 and 200. However, fine level difference adjustment is difficult in polishing. Therefore, when the desired level difference amount cannot be obtained in the polishing steps (c) and (d), the level difference amount can be further adjusted by performing the steps (e) and (f) of irradiating with plasma after the polishing steps (c) and (d).

In the method for manufacturing a semiconductor device according to the present embodiment, in the polishing steps (c) and (d), it is preferable to perform polishing such that the surface roughness Ra of each surface of the insulating layers 102 and 202 and the electrodes 103 and 203 is 5 nm or less, preferably 1 nm or less. In this case, it is possible to more reliably reduce bonding failure in hybrid bonding.

In the method for manufacturing a semiconductor device according to the present embodiment, the resin material contained in the insulating layers 102 and 202 may contain bismaleimide, polyimide, a polyimide precursor, polyamideimide, benzocyclobutene (BCB), polybenzoxazole (PBO), or a PBO precursor. Since these materials are liquid or soluble in a solvent, the insulating layers 102 and 202 can be easily produced by, for example, spin coating or the like, and a thin layer can be easily formed. In addition, since these materials have high heat resistance, the materials can withstand high temperatures when the semiconductor chip 10 (semiconductor substrate 100) is bonded to the semiconductor substrate 200, and the substrates can be bonded to each other more reliably.

Although the embodiments of the present disclosure have been described in detail above, the present disclosure is not limited to the above embodiments, and can be applied to various embodiments. For example, in the above description, the method for manufacturing a semiconductor device has been described using the CoW bonding process as an example of hybrid bonding, but the method for manufacturing a semiconductor device according to the present embodiment may be applied to a wafer-to-wafer (W2 W) bonding process. In this case, the semiconductor substrate 100 and the semiconductor substrate 200 subjected to the steps (e) and (f) are bonded to each other by hybrid bonding without performing the step (g) of singulating the first semiconductor substrate by dicing.

### EXAMPLES

Hereinafter, the present invention will be described more specifically with reference to Examples, but the present invention is not limited to Examples. In the following Examples (Experimental Examples), a semiconductor substrate provided with an organic insulating layer and an electrode on a surface of a substrate body was prepared, and whether a level difference between the surface of the organic insulating layer and the tip end surface of the electrode could be adjusted by irradiating the semiconductor substrate with plasma was tested.

First, a test wafer corresponding to the semiconductor substrate 100 was prepared. In this preparation, a first polyimide material and a second polyimide material were prepared as materials of the organic insulating layer used for the test wafer. The first polyimide material had a glass transition temperature of 290° C. after curing, a coefficient of thermal expansion (CTE) of 100 ppm/° C. (10⁻⁶/° C.), and an elastic modulus of 2.5 GPa. The second polyimide material had a glass transition temperature of 267° C. after curing, a coefficient of thermal expansion (CTE) of 75 ppm/° C., and an elastic modulus of 3.1 GPa. The coefficient of thermal expansion of copper used for the electrode was 16.8 ppm/° C. (10⁻⁶/° C.), and the elastic modulus was 120 GPa.

Subsequently, as Experimental Example 1, as shown in FIG. 3, a large number of electrodes 103, which are copper pillars (Cu) of 10 μm square and 6 μm in height, were produced on the substrate body 101, which is a silicon substrate, by a semi-additive method. Thereafter, the first polyimide material described above was spin-coated on the substrate body 101 to cover the electrodes 103, and baked at 375° C. for 2 hours under a nitrogen atmosphere to be cured (refer to FIG. 3 (a)). Thereafter, the cured semiconductor substrate 100 was disposed in a decompression chamber, and the semiconductor substrate 100 was irradiated with argon plasma under the following plasma conditions (refer to FIG. 3 (b)).
RF output (plasma output): 500 W (watt)
Treatment time (plasma treatment time): 120 seconds
Ar flow rate (flow rate of plasma gas): 8.45×10⁻² Pa·m³/sec (50 sccm)

After the plasma irradiation was completed, the level difference D between the surface of the organic insulating layer and the tip end surface of the electrode, the surface roughness Ra of the surface of the organic insulating layer, and the surface roughness Ra of the tip end surface of the electrode were measured, and the following results were obtained.
Level difference D between the surface of the organic insulating layer and the tip end surface of the electrode: 72.4 nm
Surface roughness Ra of surface of organic insulating layer: 1.5 nm

Surface roughness Ra of tip end surface of electrode: 2.6 mm According to the test under the plasma conditions of Experimental Example 1, it was confirmed that the level difference D was in a range of 40 nm to 80 nm in which the pressure-bonding property of the hybrid bonding was good (when the elastic modulus was 2.5 GPa). In addition, it was confirmed that the surface roughness Ra of the organic insulating layer and the electrode was suppressed to a low value.

Next, as Experimental Examples 2 to 6, the first polyimide material having an elastic modulus of 2.5 GPa was used as it was, and the semiconductor substrate 100 was irradiated with plasma under different plasma conditions. Conditions other than plasma irradiation conditions were the same as in Experimental Example 1. Plasma conditions and test results in Experimental Examples 2 to 6 were as shown in Table 1 below. Note that the evaluation A in the pressure-bonding property in Table 1 indicates that the level difference D was in a range in which the pressure-bonding property of the hybrid bonding was good as described above.

TABLE 1

| | | | Experimental | Experimental | Experimental | Experimental | Experimental | Experimental |
|---|---|---|---|---|---|---|---|---|
| Item | | Unit | Example 1 | Example 2 | Example 3 | Example 4 | Example 5 | Example 6 |
| Elastic modulus of | | GPa | 2.5 | | | | | |
| organic insulating layer | | | | | | | | |
| Plasma | RF output | W | 500 | 500 | 300 | 300 | 500 | 500 |
| conditions | Treatment time | s | 120 | 65 | 120 | 100 | 100 | 90 |
| | Ar flow rate | sccm | 50 | 150 | 150 | 150 | 50 | 150 |

| | | | | | | | |
|---|---|---|---|---|---|---|---|
| Level difference D between | nm | 72.4 | 63.0 | 70.0 | 60.0 | 60.2 | 80.1 |
| electrode and organic | | | | | | | |
| insulating layer | | | | | | | |
| Surface roughness Ra of | nm | 1.5 | 1.2 | 1.3 | 1.2 | 1.3 | 1.3 |
| organic insulating layer | | | | | | | |
| Surface roughness | nm | 2.6 | 4.6 | 4.0 | 3.8 | 2.9 | 5.0 |
| Ra of electrode | | | | | | | |
| Pressure-bonding property | | A | A | A | A | A | A |
| (estimated from protrusion | | | | | | | |
| amount) | | | | | | | |

Next, as Experimental Examples 7 to 10, the second polyimide material having an elastic modulus of 3.1 GPa was used, and the semiconductor substrate was irradiated with plasma by changing the plasma conditions. Conditions other than the elastic modulus of the material of the organic insulating layer and the plasma irradiation conditions were the same as in Experimental Example 1. Plasma conditions and test results in Experimental Examples 7 to 10 were as shown in Table 2 below. When the elastic modulus was 3.1 GPa and the level difference D was in the range of 15 nm to 50 nm, the pressure-bonding property of the hybrid bonding was good, and this was evaluated as evaluation A. In Experimental Examples 7 to 10, it was confirmed that the surface roughness Ra of the organic insulating layer and the electrode was also suppressed to a low value.

TABLE 2

| | | | Experimental | Experimental | Experimental | Experimental |
|---|---|---|---|---|---|---|
| Item | | Unit | Example 7 | Example 8 | Example 9 | Example 10 |
| Elastic modulus of | | GPa | 3.1 | | | |
| organic insulating layer | | | | | | |
| Plasma | RF output | W | 50 | 10 | 50 | 50 |
| conditions | Treatment time | s | 120 | 400 | 300 | 300 |
| | Ar flow rate | sccm | 100 | 100 | 100 | 50 |

| | | | | | |
|---|---|---|---|---|---|
| Level difference D between | nm | 22.0 | 20.1 | 30.5 | 29.0 |
| electrode and organic | | | | | |
| insulating layer | | | | | |
| Surface roughness Ra of | nm | 1.2 | 2.6 | 2.4 | 2.4 |
| organic insulating layer | | | | | |
| Surface roughness | nm | 2.5 | 4.3 | 3.7 | 3.2 |
| Ra of electrode | | | | | |
| Pressure-bonding property | | A | A | A | A |
| (estimated from protrusion | | | | | |
| amount) | | | | | |

Next, Experimental Examples 11 to 17 were conducted as a further experimental example. In Experimental Examples 11 to 17, similarly to Experimental Example 1, the first polyimide material having an elastic modulus of 2.5 GPa was used, and the semiconductor substrate 100 was irradiated with plasma by changing the plasma conditions. Conditions other than plasma irradiation conditions were the same as in Experimental Example 1. Plasma conditions and test results in Experimental Examples 11 to 17 were as shown in Table 3 below. In Experimental Examples 11 to 17, the plasma conditions were greatly changed as compared with Experimental Example 1 and the like, and the test was performed.

TABLE 3

| | | | Experimental | Experimental | Experimental | Experimental | Experimental | Experimental | Experimental |
|---|---|---|---|---|---|---|---|---|---|
| Item | | Unit | Example 11 | Example 12 | Example 13 | Example 14 | Example 15 | Example 16 | Example 17 |
| Elastic modulus of | | GPa | 2.5 | | | | | | |
| organic insulating layer | | | | | | | | | |
| Plasma | RF output | W | 500 | 150 | 150 | 150 | 150 | 500 | 500 |
| conditions | Treatment time | s | 30 | 120 | 120 | 30 | 30 | 30 | 120 |
| | Ar flow rate | sccm | 150 | 50 | 150 | 50 | 150 | 50 | 150 |

| | | | | | | | | |
|---|---|---|---|---|---|---|---|---|
| Level difference D between | nm | 45.7 | 39.5 | 49.4 | 21.1 | 11.6 | 26.1 | 100.6 |
| electrode and organic | | | | | | | | |
| insulating layer | | | | | | | | |
| Surface roughness Ra of | nm | 0.9 | 1.2 | 0.9 | 1.2 | 1.5 | 0.7 | 1.6 |
| organic insulating layer | | | | | | | | |
| Surface roughness Ra of | nm | 3.4 | 2.3 | 2.4 | 2.0 | 2.6 | 1.6 | 5.4 |
| electrode | | | | | | | | |

As shown in Experimental Examples 11 to 17, it has been confirmed that the level difference D and the surface roughness Ra can be changed (that is, various adjustments) by changing the plasma conditions. It has been considered that it is possible to provide a case where the level difference D is not sufficient (for example, Experimental Example 15) and a case where the level difference D is too large (for example, Experimental Example 17) for hybrid bonding by making the desired level difference D and surface roughness Ra by a treatment such as CMP before plasma treatment.

As described above, according to the above experimental examples, it has been confirmed that when both the organic insulating layer and the electrodes are irradiated with plasma, the amount of etching with plasma can be made different depending on the difference in elastic modulus between the organic insulating layer and the electrodes. Then, in the plasma treatment for such an organic insulating layer or the like, it has been confirmed that a desired level difference can be easily provided between the surface of the organic insulating layer and the tip end surfaces of the electrodes in the semiconductor substrate, in the hybrid bonding method using the organic insulating layer by changing the conditions of the plasma according to the materials of the organic insulating layer and the electrodes, the difference in elastic modulus between the organic insulating layer and the electrodes, or the like.

### REFERENCE SIGNS LIST

1 Semiconductor device
10 Semiconductor chip
20 Semiconductor substrate
100, 200 Semiconductor substrate
101, 201 Substrate body
101a, 201a Surface
102, 202 Insulating layer
102a, 202a Surface
102b Insulating layer part
103, 203 Electrode
103a, 203a Tip end surface
D Level difference

1. A method for manufacturing a semiconductor device comprising:
preparing a first semiconductor substrate including a first substrate body, and a first organic insulating layer and a first electrode which are provided on a surface of the first substrate body; and
irradiating a surface of the first semiconductor substrate with plasma,
wherein, in the irradiating with plasma, at least the first organic insulating layer is etched with plasma such that a surface of the first organic insulating layer is closer to the first substrate body than a tip end surface of the first electrode.

2. The method for manufacturing a semiconductor device according to claim 1,
wherein, in the irradiating with plasma, the first semiconductor substrate is irradiated with argon plasma.

3. The method for manufacturing a semiconductor device according to claim 1 or 2,
wherein, in the irradiating with the plasma, a flow rate of the plasma gas is 3.38×10⁻² Pa·m³/sec (20 sccm) to 1.69 Pa·m³/sec (1,000 sccm).

4. The method for manufacturing a semiconductor device according to any one of claims 1 to 3,
wherein, in the irradiating with the plasma, a plasma output is 10 W to 1,000 W.

5. The method for manufacturing a semiconductor device according to any one of claims 1 to 4,
wherein, in the irradiating with plasma, a plasma treatment time is 30 seconds or more.

6. The method for manufacturing a semiconductor device according to any one of claims 1 to 5,
wherein, the first organic insulating layer has an elastic modulus of 7.5 GPa or less.

7. The method for manufacturing a semiconductor device according to any one of claims 1 to 6,
wherein, in the irradiating with plasma, the surface of the first semiconductor substrate is irradiated with plasma such that a level difference distance between the surface of the first organic insulating layer and the tip end surface of the first electrode is 40 nm to 100 nm.

8. The method for manufacturing a semiconductor device according to any one of claims 1 to 6,
wherein, in the irradiating with plasma, the surface of the first semiconductor substrate is irradiated with plasma such that a level difference distance between the surface of the first organic insulating layer and the tip end surface of the first electrode is 60 nm to 80 nm.

9. The method for manufacturing a semiconductor device according to any one of claims 1 to 8, further comprising:
polishing the first organic insulating layer and the first electrode which are provided on the surface of the first semiconductor substrate,
wherein the polishing the first semiconductor substrate is performed before the irradiating with the plasma.

10. The method for manufacturing a semiconductor device according to claim 9,
wherein, in the polishing the first semiconductor substrate, polishing is performed such that a surface roughness Ra of each of the surfaces of the first organic insulating layer and the first electrode is 5 nm or less.

11. The method for manufacturing a semiconductor device according to any one of claims 1 to 10, further comprising:
preparing a second semiconductor substrate including a second substrate body, and a second organic insulating layer and a second electrode which are provided on a surface of the second substrate body;
aligning the second electrode of the second semiconductor substrate with the first electrode of the first semiconductor substrate; and
heating and pressurizing the first semiconductor substrate and the second semiconductor substrate to bond the first organic insulating layer and the second organic insulating layer to each other and bond the first electrode and the second electrode to each other.

12. The method for manufacturing a semiconductor device according to claim 11, further comprising:
irradiating a surface of the second semiconductor substrate with plasma,
wherein, in the irradiating the second semiconductor substrate with plasma, at least the second organic insulating layer is etched with plasma such that a surface of the second organic insulating layer is closer to the second substrate body than a tip end surface of the second electrode.

13. The method for manufacturing a semiconductor device according to any one of claims 1 to 12,
wherein, the resin material contained in the first organic insulating layer contains bismaleimide, polyimide, a polyimide precursor, polyamideimide, benzocyclobutene (BCB), polybenzoxazole (PBO), or a PBO precursor.
